(19) United States
(12) Patent Application Publication
(10) Pub. No.: US 2025/0040318 A1
(43) Pub. Date: Jan. 30, 2025

(54) ELECTRONIC DEVICE AND MANUFACTURING METHOD THEREOF

(71) Applicant: InnoLux Corporation, Miao-Li County (TW)

(72) Inventors: Zhi-Wei ZHANG, Miao-Li County (TW); Hua-Pin CHEN, Miao-Li County (TW); Shuai WANG, Miao-Li County (TW); Chien-Hao KUO, Miao-Li County (TW)

(21) Appl. No.: 18/757,841

(22) Filed: Jun. 28, 2024

(30) Foreign Application Priority Data
Jul. 28, 2023 (CN) 202310936606.5

(51) Int. Cl. F21V 19/00; F21Y 113/00; F21Y 115/10

(52) U.S. Cl. CPC H01L 33/56; F21Y 2115/10; H01L 25/0753; H10K 50/844; H10K 59/873; H10K 59/95

(57) ABSTRACT

An electronic device includes: a substrate; a plurality of electronic components disposed on the substrate, wherein there is a first pitch between two adjacent electronic components in a first direction; and a protective glue disposed on the substrate and the electronic components, and provided with at least one groove disposed between the two adjacent electronic components, wherein a distance between an edge of one of the two adjacent electronic components and the at least one groove satisfies an equation:

$$0.3 mm \leq D 1 < ( P / 2 ) ,$$

where D1 is the distance between the edge of the one of the two adjacent electronic components and the at least one groove, and P is the first pitch.

### CROSS-REFERENCE TO RELATED APPLICATIONS

This application claims the benefits of the Chinese Patent Application Serial Number 202310936606.5, filed on Jul. 28, 2023, the subject matter of which is incorporated herein by reference.

### BACKGROUND

### Field of the Disclosure

The present disclosure relates to an electronic device and a manufacturing method thereof and, more particularly, to an electronic device with protective glue.

### Description of Related Art

With the advancement of science and technology and in order to meet the needs of consumers, the requirements for resolution and contrast of electronic devices in the market continue to increase. In general, with the direct-type backlight modules, the contrast of electronic devices can be improved through regional light control, or the resolution of electronic devices can be improved by adjusting the diode size, thereby becoming more applicable than the edge-type backlight modules.

However, electronic devices using direct-type backlight modules still have problems such as poor light extraction efficiency, high cost, or complicated manufacturing steps. Therefore, there is an urgent need to provide an electronic device and a manufacturing method thereof to alleviate and/or obviate the above defects.

### SUMMARY

The present disclosure provides an electronic device, which includes: a substrate; a plurality of electronic components disposed on the substrate, wherein there is a first pitch between two adjacent electronic components in a first direction; and a protective glue disposed on the substrate and the electronic components, and provided with at least one groove disposed between the two adjacent electronic components, wherein a distance between an edge of one of the two adjacent electronic components and the at least one groove satisfies an equation:

$$0.3 mm \leq D 1 < ( P / 2 ) ,$$

where D1 is the distance between the edge of the one of the two adjacent electronic components and the at least one groove, and P is the first pitch.

The present disclosure further provides a manufacturing method of an electronic device, which includes the steps of: providing a substrate; disposing a plurality of electronic components on the substrate so that there is a first pitch between two adjacent electronic components in a first direction; and applying a protective glue to the electronic components and the substrate, so that the protective glue forms at least one groove, wherein the at least one groove is disposed between the two adjacent electronic components, wherein a distance between an edge of one of the two adjacent electronic components and the at least one groove satisfies an equation:

$$0.3 mm \leq D 1 < ( P / 2 ) ,$$

where D1 is the distance between the edge of the one of the two adjacent electronic components and the at least one groove, and P is the first pitch.

Other novel features of the disclosure will become more apparent from the following detailed description when taken in conjunction with the accompanying drawings.

### BRIEF DESCRIPTION OF DRAWINGS

FIG. 1 is a schematic cross-sectional view of an electronic device according to an embodiment of the present disclosure;

FIG. 2 is a schematic cross-sectional view of an electronic device according to an embodiment of the present disclosure;

FIG. 3 is a schematic cross-sectional view of an electronic device according to an embodiment of the present disclosure;

FIG. 4 is a block diagram of a manufacturing method of an electronic device according to an embodiment of the present disclosure; and

FIG. 5 is a schematic flowchart of a manufacturing method of an electronic device according to an embodiment of the present disclosure.

### DETAILED DESCRIPTION OF EMBODIMENT

The implementation of the present disclosure is illustrated by specific embodiments to enable persons skilled in the art to easily understand the other advantages and effects of the present disclosure by referring to the disclosure contained therein. The present disclosure is implemented or applied by other different, specific embodiments. Various modifications and changes can be made in accordance with different viewpoints and applications to details disclosed herein without departing from the spirit of the present disclosure.

It should be noted that, in this article, unless otherwise specified, having “one” element is not limited to having a single said element, but may include one or more said elements. Furthermore, the ordinal numbers used in the specification and claims, such as “first” and “second”, etc., are used to modify the elements of the claim, and they do not imply or represent that the claimed element has any previous ordinal number. It does not represent the order between a certain claimed element and another claimed element, or the order in the manufacturing method. The use of these ordinal numbers is only used to enable one claimed element with a certain name to be clearly distinguished from another claimed element with the same name.

In the entire specification and the appended claims of the present disclosure, certain words are used to refer to specific components. Those skilled in the art should understand that electronic device manufacturers may refer to the same components by different names. The present disclosure does not intend to distinguish those components with the same function but different names. In the claims and the following description, the words “comprise”, “include” and “have” are open type language, and thus they should be interpreted as meaning “including but not limited to . . . ”. Therefore, when the terms “comprise”, “include” and/or “have” are used in the description of the present disclosure, they specify the existence of corresponding features, regions, steps, operations and/or components, but do not exclude the existence of one or more corresponding features, regions, steps, operations and/or components.

In addition, in the specification and claims, the term “almost”, “about”, “approximately” or “substantially” usually means within 20%, 10%, 5%, 3%, 2%, 1% or 0.5% of a given value or range. The quantity the given value is an approximate quantity, which means that the meaning of “almost”, “about”, “approximately” or “substantially” may still be implied in the absence of a specific description of “almost”, “about”, “approximately” or “substantially”. In addition, the terms “ranging from the first value to the second value” and “range between the first value and the second value” indicate that the range includes the first value, the second value, and other values between the first value and the second value.

Unless otherwise defined, all terms (including technical and scientific terms) used here have the same meanings as commonly understood by those skilled in the art of the present disclosure. It is understandable that these terms, such as those defined in commonly used dictionaries, should be interpreted as having a meaning consistent with the relevant technology and the background or context of the present disclosure, rather than in an idealized or excessively formal interpretation, unless specifically defined.

In addition, relative terms such as “below” or “bottom”, and “above” or “top” may be used in the embodiments to describe the relationship between one component and another component in the drawing. It can be understood that, if the device in the drawing is turned upside down, the components described on the “lower” side will become the components on the “upper” side. When the corresponding member (such as a film or region) is described as “on another member”, it may be directly on the other member, or there may be other members between the two members. On the other hand, when a member is described as “directly on another member”, there is no member between the two members. In addition, when a member is described as “on another member”, the two members have a vertical relationship in the top view direction, and this member may be above or below the other member, while the vertical relationship depends on the orientation of the device.

In the present disclosure, the thickness, length and width can be measured by using an optical microscope, and the thickness can be measured by the cross-sectional image in an electron microscope, but it is not limited thereto. In addition, there may be a certain error in any two values or directions used for comparison. If the first value is equal to the second value, it implies that there may be an error of about 10% between the first value and the second value. If the first direction is perpendicular to the second direction, the angle between the first direction and the second direction may be 80 to 100 degrees. If the first direction is parallel to the second direction, the angle between the first direction and the second direction may be 0 to 10 degrees.

It should be noted that the technical solutions provided by the different embodiments described hereinafter may be used interchangeably, combined or mixed to form another embodiment without violating the spirit of the present disclosure.

The electronic device of the present disclosure may include a sensing device, a display device, a light emitting device, an antenna device, a touch display, a curved display or a free shape display, but not limited thereto. The electronic components in electronic devices may include passive components and active components, such as capacitors, resistors, inductors, diodes, transistors, etc. The diodes include light emitting diodes or photodiodes. The light emitting diodes include organic light emitting diodes (OLEDs), sub-millimeter light emitting diodes (mini LEDs), micro light emitting diodes (micro LEDs) or quantum dot (QD) light emitting diodes (which may be QLED, QDLED) or other suitable materials or any arrangement and combination of the above materials, but not limited thereto. The electronic device may be, for example, a bendable or flexible electronic device, but not limited thereto. The sensing device may be, for example, a sensing device for detecting capacitance changes, light, heat energy or ultrasonic waves, but not limited thereto. The display device may include, for example, light emitting diodes, fluorescent materials, phosphor materials, other suitable display media, or combinations of the foregoing, but not limited thereto. The display device may, for example, include a tiled display device, but not limited thereto. The antenna device may be, for example, a liquid crystal antenna, but not limited thereto. In addition, the shape of the electronic device may be, for example, a rectangle, a circle, a polygon, a shape with curved edges, a curved surface, or other suitable shapes. The electronic device may have peripheral systems such as a drive system, a control system, a light source system, a shelf system, etc. It should be noted that the electronic device may be any combination of the above, but it is not limited thereto.

FIG. 1 is a schematic cross-sectional view of an electronic device according to an embodiment of the present disclosure.

In one embodiment of the present disclosure, as shown in FIG. 1, the electronic device may include: a substrate 1; a plurality of electronic components 2 disposed on the substrate 1, wherein, in a first direction, there is a first pitch P between adjacent electronic components 2; and a protective glue 3 arranged on the substrate 1 and the electronic component 2, wherein the protective glue 3 has at least one groove G, and the at least one groove G is disposed between two adjacent electronic components 2. The distance D1 between the edge 21 of one of the two adjacent electronic components 2 and the at least one groove G satisfies the following equation (1):

$$0.3 mm \leq D 1 < ( P / 2 ) . \qquad ( 1 )$$

In the present disclosure, the “first pitch P” may refer to, for example, the distance between the centers of two adjacent electronic components 2 in the first direction X. Alternatively, the “first pitch P” may refer to, for example, the distance between the same-side edges of two adjacent electronic components 2 in the first direction X. The “distance D1” may refer to, for example, the shortest distance between the edge 21 of the electronic component 2 and the adjacent groove G in the first direction X. In one embodiment, the “distance D1” may, for example, refer to the distance between the groove G and the adjacent electronic component 2 in the first direction X at a height H2 of the electronic component from the substrate 1. The “first direction X” refers to, for example, a direction perpendicular to the normal direction Z of the substrate 1. In the present disclosure, the distance D1 between the edge 21 of one of the two adjacent electronic components 2 and the at least one groove G may be designed to satisfy the relationship of the above equation (1), so as to increase the light emission amount of the electronic device thereby improving light extraction efficiency or saving costs. When the distance D1 satisfies the restrictions of the above equation (1), each distance D1 may be the same or different.

In the present disclosure, the material of the substrate 1 may include metal, alloy, polycarbonate (PC), polyimide (PI), polypropylene (PP), polyethylene terephthalate (PET), epoxy resin, bismaleimide, triazine or other plastic or polymer materials, or a combination thereof, but the present disclosure is not limited thereto. In the present disclosure, the electronic component 2 may include a light emitting diode, such as an organic light emitting diode (OLED), a sub-millimeter light emitting diode (mini LED), or a micro light emitting diode (micro LED) or quantum dot light emitting diode (quantum dot LED, which may include QLED, QDLED), fluorescence, phosphor or other suitable materials, or a combination thereof, but the present disclosure is not limited thereto.

In the present disclosure, the material of the protective glue 3 may be, for example, silicone or other transparent glue, but the present disclosure is not limited thereto. In the present disclosure, the penetration rate of the protective glue 3 may be greater than or equal to 90%, such as greater than or equal to 92%, greater than or equal to 95%, or greater than or equal to 97%, but the present disclosure is not limited thereto. In the present disclosure, the viscosity of the protective glue 3 may be 200 mPa·s to 8000 mPa·s, such as 500 mPa·s to 8000 mPa·s, 500 mPa·s to 7000 mPa·s, or 200 mPa·s to 5000 mPa·s, but the present disclosure is not limited thereto. In the present disclosure, the refractive index of the protective glue 3 may be greater than 1.3, such as greater than or equal to 1.4, or greater than or equal to 1.5, but the present disclosure is not limited thereto. When the characteristics of the protective glue 3 meet the above restrictions, the protective glue 3 may have good processing characteristics, or the light emission amount of the electronic device may be increased.

In the present disclosure, the height H1 of the protective glue 3 may be greater than or equal to 1.2 times the height H2 of the electronic component 2, and smaller than or equal to 3 times the height H2 of the electronic component 2 (that is, it satisfies: 1.2×H2≤H1≤3×H2). In one embodiment of the present disclosure, the height H1 of the protective glue 3 may be greater than or equal to 1.5 times the height H2 of the electronic component 2, and smaller than or equal to 2 times the height H2 of the electronic component 2 (that is, it satisfies: 1.5×H2≤H1≤2×H2). The “height H1 of the protective glue 3” refers to, for example, the distance between the upper surface 11 of the substrate 1 and the upper surface 31 of the protective glue 3 in the normal direction Z of the substrate 1. The “height H2 of the electronic component 2” refers to, for example, the distance between the upper surface 11 of the substrate 1 and the upper surface 22 of the electronic component 2 in the normal direction Z of the substrate 1. When the height H1 of the protective glue 3 meets the above restrictions, the electronic device may achieve a good protection effect, or the light emission amount of the electronic device may be increased. In one embodiment of the present disclosure, the upper surface of the protective glue 3 is a plane.

In the present disclosure, the groove G may be, for example, a portion where no protective glue 3 is provided between two adjacent electronic components 2. In one embodiment of the present disclosure, the width W1 of the groove G refers to, for example, the average width of the trench G in the first direction X, but the present disclosure is not limited thereto. In other embodiments of the present disclosure, the width W1 of the groove G refers to, for example, the width of the groove G in the first direction X at the height H2 of the electronic component from the substrate 1. In the present disclosure, the width W1 of the groove G may be greater than or equal to 0.05 mm (that is, the minimum value of the width W1 of the groove G may be greater than or equal to 0.05 mm), for example, greater than or equal to 0.1 mm, greater than or equal to 0.5 mm, or greater than or equal to 1 mm, but the present disclosure is not limited thereto. In the present disclosure, the width W1 of the groove G may satisfy the following equation (2):

$$( P - W - 2 \times D 1 ) \leq W 1 < ( P - W ) , \qquad ( 2 )$$

where P refers to the first pitch between two adjacent electronic components 2 in the first direction X; W refers to the size of the electronic component 2 in the first direction X (i.e., the width or length of the electronic component 2), for example, in FIG. 1, the size of the electronic component 2 is the width of the electronic component 2 in the first direction X; D1 refers to the distance between the edge 21 of one of the two adjacent electronic components 2 and the at least one groove G. In one embodiment, the width W1 of the groove G further satisfies the following equation (3):

$$( P - W - 2 \times D 1 ) \leq W 1 < ( P - 2 \times W ) . \qquad ( 3 )$$

When the width W1 of the groove G complies with the above equation (2) and/or the above equation (3), the light emission amount of the electronic device may be improved. In addition, when the width W1 of each groove G complies with the above equation (2) and/or the above equation (3), the width W1 of each groove G may be the same or different.

In one embodiment of the present disclosure, as shown in FIG. 1, the height of the groove G may be approximately equal to the height H1 of the protective glue 3. Therefore, when viewed in the normal direction Z of the substrate 1, the groove G may expose a portion of the substrate 1. In more detail, the groove G may expose a portion of the upper surface 11 of the substrate 1. The “height of the groove” refers to, for example, the distance from the bottom of the groove G to the upper surface 31 of the protective glue 3 in the normal direction Z of the substrate 1. In the present disclosure, the shape of the groove G is not particularly limited, and the shape of each groove G may be the same or different. For example, in one embodiment of the present disclosure, as shown in FIG. 1, in a cross-section, the shapes of the grooves G may all be rectangular, but the present disclosure is not limited thereto. In other embodiments of the disclosure, in a cross-section, the shape of the groove G may be U-shape, V-shape or other suitable shapes. In one embodiment of the present disclosure, when the shape of the groove G is rectangular, the width W1 of the groove G is substantially the same everywhere, that is, the width W1 of the groove G is substantially equal to the average width of the groove G.

In the present disclosure, the groove G may or may not be filled with medium material, and the refractive index of the protective glue 3 may be greater than the refractive index of the medium in the groove G. In one embodiment of the present disclosure, the groove G may not be filled with medium material. In other words, the medium in the groove G may be air. When the refractive index of the medium material in the groove G satisfies the above restrictions, the light provided by the electronic component may be completely reflected, so as to increase the light emission amount of the electronic device thereby achieving the purpose of improving light extraction efficiency or saving costs.

In one embodiment of the present disclosure, although not shown in the figures, the electronic device may further include an optical film disposed on the protective glue 3 to form a backlight module. The optical film may include a brightness enhancement film, a diffusion film, other suitable optical films, or a combination thereof, but the present disclosure is not limited thereto. In addition, in one embodiment of the present disclosure, although not shown in the figures, the electronic device may further include a display panel disposed on the substrate 1 to form a display device. The display panel may be, for example, a flexible display panel, a touch display panel, a curved display panel or a tiled display panel. Therefore, the electronic device may be applied to any electronic device that requires a display panel, such as monitors, mobile phones, laptops, video cameras, still cameras, music players, mobile navigators, television sets and other devices that display images, but the present disclosure is not limited thereto. In addition, when the electronic device is a tiled display system, the electronic device may be applied to any electronic device that needs to display large images, such as a video wall or a billboard, but the present disclosure is not limited thereto.

FIG. 2 is a schematic cross-sectional view of an electronic device according to an embodiment of the present disclosure. The electronic device of FIG. 2 is similar to that of FIG. 1 except for the following differences.

In one embodiment of the present disclosure, as shown in FIG. 2, in a cross-section, the shape of each groove G may be different, and the shape of the groove G may be U-shape or V-shape. However, the present disclosure is not limited thereto. In this embodiment, the distance D1 between the edge 21 of one of the two adjacent electronic components 2 and the at least one groove G, for example, refers to the measured distance between the edge 21 of the electronic component 2 and the groove G in the first direction X at the height H2 of the electronic component from the substrate 1. In this embodiment, the width W1 of the groove G refers to, for example, the width of the groove G in the first direction X at the height H2 of the electronic component from the substrate 1. In addition, since the shape of each groove G may be different, when the distance D1 complies with the restrictions of the above equation (1), each distance D1 may be the same or different. Similarly, when the width W1 of each groove G complies with the above restrictions, the width W1 of each groove G may be the same or different.

In one embodiment of the present disclosure, as shown in FIG. 2, the height of the groove G may be smaller than the height H1 of the protective glue 3. Therefore, when viewed in the normal direction Z of the substrate 1, the groove G does not expose a portion of the substrate 1. In one embodiment of the present disclosure, the distance D2 between the upper surface 11 of the substrate 1 and the groove G may be smaller than one-third of the height H2 of the electronic component 2 (i.e., D2<⅓×H2). More specifically, in the normal direction Z of the substrate 1, the minimum distance D2 between the upper surface 11 of the substrate 1 and the bottom of the groove G may be smaller than one-third of the height H2 of the electronic component 2. Since the shape of each groove G may be different, when the distance D2 complies with the above restrictions, each distance D2 may be the same or different.

In this embodiment, the materials of the substrate 1, the electronic component 2 and the protective glue 3 may be as described above, and thus a detailed description is deemed unnecessary. Other features of the protective glue 3 and the groove G may be described as described above and thus will not be described again here.

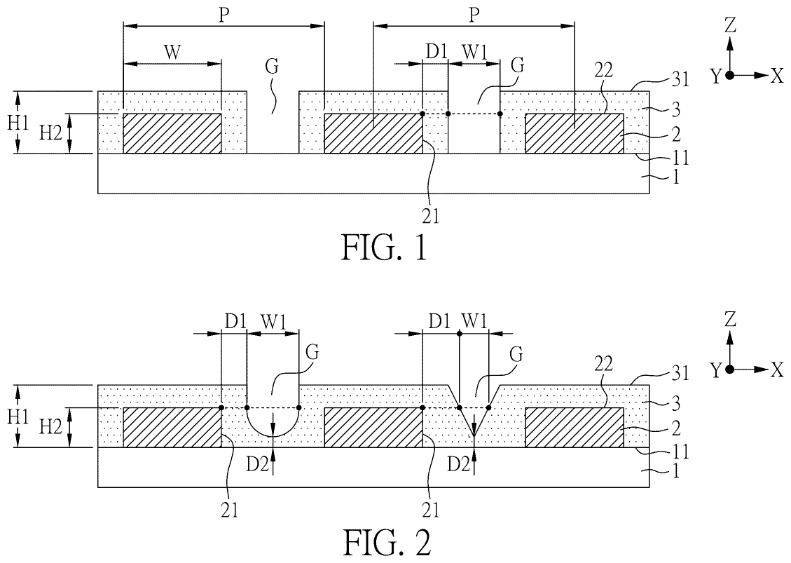

FIG. 3 is a schematic cross-sectional view of an electronic device according to one embodiment of the present disclosure. The electronic device of FIG. 3 is similar to that of FIG. 1 except for the following differences.

In one embodiment of the present disclosure, as shown in FIG. 3, the electronic device may include a plurality of electronic components 2 (such as a first electronic component 2A and a second electronic component 2B), which are disposed on the substrate 1. The groove G of the protective glue 3 is disposed between the first electronic component 2A and the second electronic component 2B. The groove G may include a first sub-groove G1 and a second sub-groove G2, wherein the first sub-groove G1 is disposed closest to the first electronic component 2A, and the second sub-groove G2 is disposed closest to the second electronic component 2B. In one embodiment of the present disclosure, a portion of protective glue 3 or other materials may be included between the first sub-groove G1 and the second sub-groove G2. In the electronic device of the present disclosure, the light emission amount of the electronic device may be increased through the arrangement of the first sub-groove G1 and the second sub-groove G2.

In one embodiment of the present disclosure, as shown in FIG. 3, the width W1 of the groove G refers to, for example, the maximum width between the first sub-groove G1 and the second sub-groove G2 in the first direction X. More specifically, the width W1 of the groove G, for example, refers to the maximum distance between the edge G11 of the first sub-groove G1 and the edge G21 of the second sub-groove G2 in the first direction X. The width W1 of the groove G may be greater than or equal to 0.05 mm, such as greater than or equal to 0.1 mm, greater than or equal to 0.5 mm, or greater than or equal to 1 mm, but the present disclosure is not limited thereto. The width W1 of the groove G may satisfy the above equation (2) and/or the above equation (3), which will not be described again here. In addition, in this embodiment, the materials of the substrate 1, the electronic component 2 and the protective glue 3 may be as described above and other features of the protective glue 3 and the groove G may be as described above, and thus a detailed description is deemed unnecessary.

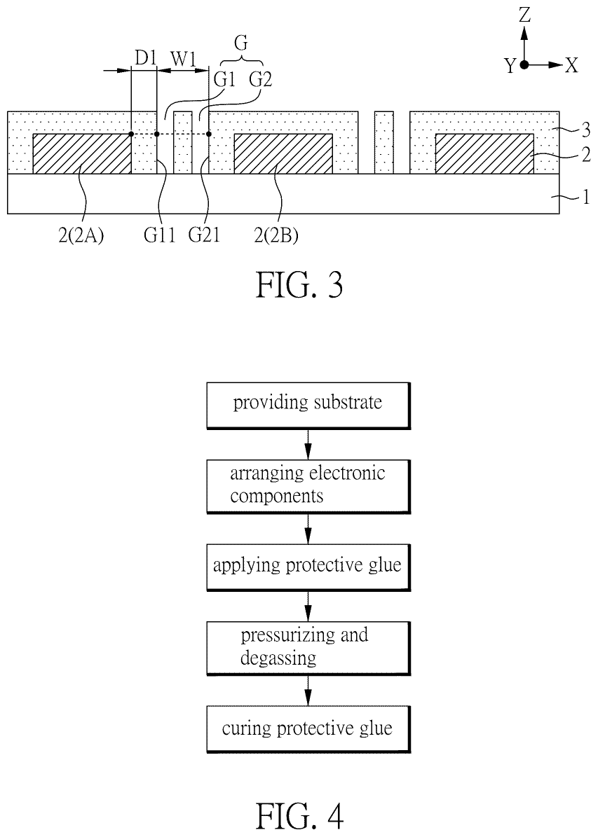

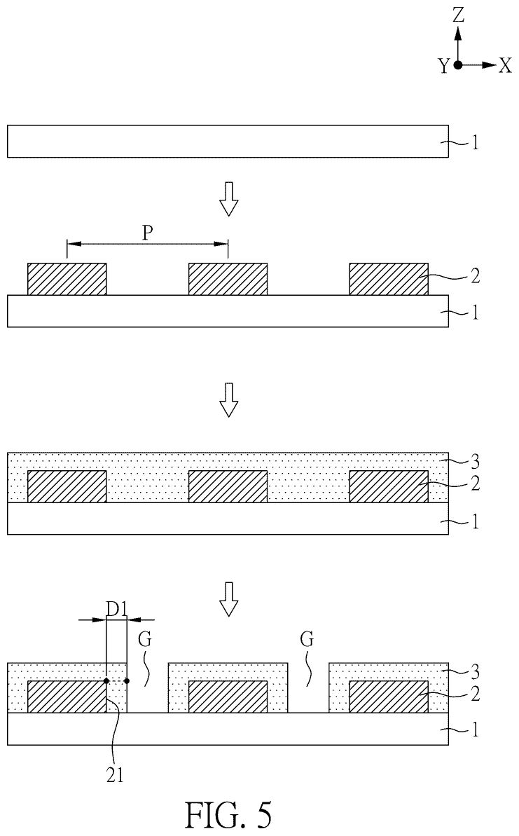

FIG. 4 is a block diagram illustrating a manufacturing method of an electronic device according to an embodiment of the present disclosure. FIG. 5 is a schematic flowchart illustrating a manufacturing method of an electronic device according to an embodiment of the present disclosure.

In one embodiment of the present disclosure, as shown in FIG. 4 and FIG. 5, the manufacturing method of an electronic device may include: providing a substrate 1; disposing a plurality of electronic components 2 on the substrate 1, so that there is a first pitch P between two adjacent electronic components 2 in the first direction X; and applying a protective glue 3 on the electronic components 2 and the substrate 1, so that the protective glue 3 forms at least one groove G, wherein the at least one groove G is disposed between two adjacent electronic components 2 to form an electronic device as shown in FIG. 1. The distance D1 between the edge 21 of one of the two adjacent electronic components 2 and the at least one groove G satisfies the following equation (1):

$$0.3 mm \leq D 1 < ( P / 2 ) . \qquad ( 1 )$$

In the present disclosure, by using the protective glue 3 to form at least one groove G, and enabling the distance D1 between the edge 21 of one of the two adjacent electronic components 2 and the at least one groove G to satisfy the above equation (1), it is able to achieve the effect of simplifying process steps or saving costs when increasing the light emission amount of the electronic device. In the present disclosure, the materials of the substrate 1, the electronic component 2 and the protective glue 3 may be as described above, and other features of the electronic component 2, the protective glue 3 and the groove G may be as described above, so that a detailed description is deemed unnecessary.

In the present disclosure, the protective glue 3 may be applied to the electronic component 2 and the substrate 1 through a suitable method. For example, in one embodiment of the present disclosure, as shown in FIG. 4 and FIG. 5, the protective glue 3 may be applied through a suitable coating method to the electronic component 2 and the substrate 1. The suitable coating method may be, for example, dip coating, spin coating, roller coating, blade coating, or spray coating. However, the present disclosure is not limited thereto. In the present disclosure, the protective glue 3 may be formed with at least one groove G through a suitable method. For example, in one embodiment of the present disclosure, as shown in FIG. 4, after the protective glue 3 is applied to the electronic component 2 and the substrate 1, a step of molding the protective glue 3 to form at least one groove G may be further included, but the present disclosure is not limited thereto.

In one embodiment of the present disclosure, as shown in FIG. 4 and FIG. 5, after the step of forming at least one groove G in the protective glue 3, the step of curing the protective glue 3 may be further included, so that the groove G is shaped. In one embodiment of the present disclosure, before the step of curing the protective glue 3, a step of pressurizing and degassing the protective glue 3 may be included to remove air bubbles in the protective glue 3, thereby improving the reliability of the protective glue 3. In the present disclosure, the conditions for pressurizing and degassing are not particularly limited. For example, a pressurizing and degassing machine may be used to perform pressurizing and degassing at a pressure of 1 kgf to 10 kgf (for example, 5 kgf) and a temperature of 20° C. to 80° C. (for example, 40° C. to 60° C.), but the present disclosure is not limited thereto. In one embodiment of the present disclosure, although not shown in the figures, after the step of curing the protective glue 3, it may further include disposing an optical film on the protective glue 3 to form a backlight module. In one embodiment of the present disclosure, although not shown in the figures, after the step of curing the protective glue 3, it may further include disposing a display panel on the substrate 1 to form a display device. In the present disclosure, the optical film and the display panel may be as described above and will not be described again.

In another embodiment of the present disclosure, although not shown in the figures, after the step of arranging a plurality of electronic components 2 on the substrate 1, a step of arranging a mold on the substrate 1 and then filling glue may be further performed to form the protective glue 3 on the electronic component 2 and the substrate 1 and to form at least one groove G in the protective glue 3. Then, the groove G may be shaped through the steps of pre-curing and/or curing the protective glue 3. In addition, before the steps of pre-curing and/or curing the protective glue 3, a step of pressurizing and degassing the protective glue 3 may be included to remove air bubbles in the protective glue 3, thereby improving the reliability of the protective glue 3. In this embodiment, the conditions for pressurizing and degassing may be as described above and will not be described again.

The aforementioned specific embodiments should be construed as merely illustrative, and not limiting the rest of the present disclosure in any way.

1. An electronic device, comprising:
a substrate;
a plurality of electronic components disposed on the substrate, wherein there is a first pitch between two adjacent electronic components in a first direction; and
a protective glue disposed on the substrate and the electronic components, and provided with at least one groove disposed between the two adjacent electronic components, wherein a distance between an edge of one of the two adjacent electronic components and the at least one groove satisfies an equation:
$$0.3 mm \leq D 1 < ( P / 2 ) ,$$
where D1 is the distance between the edge of the one of the two adjacent electronic components and the at least one groove, and P is the first pitch.

2. The electronic device as claimed in claim 1, wherein a height of the protective glue is greater than or equal to 1.2 times that of one of the electronic components, and smaller than or equal to 3 times that of the one of the electronic components.

3. The electronic device as claimed in claim 1, wherein a width of the at least one groove is greater than or equal to 0.05 mm.

4. The electronic device as claimed in claim 1, wherein a width of the at least one groove satisfies an equation:
$$( P - W - 2 \times D 1 ) \leq W 1 < ( P - W ) ,$$
where W1 is a width of the at least one groove, and W is a size of one of the electronic components in the first direction.

5. The electronic device as claimed in claim 1, wherein a distance from a surface of the substrate to the groove is smaller than one-third of a height of one of the electronic components.

6. The electronic device as claimed in claim 1, wherein a refractive index of the protective glue is greater than that of a medium in the groove.

7. The electronic device as claimed in claim 1, wherein a penetration rate of the protective glue is greater than or equal to 90%.

8. The electronic device as claimed in claim 1, wherein a refractive index of the protective glue is greater than 1.3.

9. The electronic device as claimed in claim 1, wherein an upper surface of the protective glue is a flat surface.

10. The electronic device as claimed in claim 1, wherein a width of the at least one groove satisfies an equation:
$$( P - W - 2 \times D 1 ) \leq W 1 < ( P - 2 \times W ) ,$$
where W1 is the width of the at least one groove, and W is a size of one of the electronic components in the first direction.

11. The electronic device as claimed in claim 1, wherein a shape of the groove is rectangular.

12. The electronic device as claimed in claim 11, wherein a height of the groove is equal to that of the protective glue.

13. The electronic device as claimed in claim 1, wherein a shape of the groove is U-shaped or V-shaped.

14. The electronic device as claimed in claim 13, wherein a height of the groove is smaller than that of the protective glue.

15. The electronic device as claimed in claim 14, wherein a distance between an upper surface of the substrate and the groove is smaller than one-third of a height of the electronic component.

16. The electronic device as claimed in claim 1, wherein the groove includes a first sub-groove and a second sub-groove, the first sub-groove is disposed closest to one of the two adjacent electronic components, the second sub-groove is disposed closest to the other one of the two adjacent electronic components, and a portion of the protective glue is included between the first sub-groove and the second sub-groove.

17. A manufacturing method of an electronic device, comprising the steps of:
providing a substrate;
disposing a plurality of electronic components on the substrate so that there is a first pitch between two adjacent electronic components in a first direction; and
applying a protective glue to the electronic components and the substrate, so that the protective glue forms at least one groove, wherein the at least one groove is disposed between the two adjacent electronic components,
wherein a distance between an edge of one of the two adjacent electronic components and the at least one groove satisfies an equation:
$$0.3 mm \leq D 1 < ( P / 2 ) ,$$
where D1 is the distance between the edge of the one of the two adjacent electronic components and the at least one groove, and P is the first pitch.

18. The manufacturing method as claimed in claim 17, further comprising the step of molding the protective glue to form the groove.

19. The manufacturing method as claimed in claim 17, further comprising the step of curing the protective glue.

20. The manufacturing method as claimed in claim 19, further comprising, before the step of curing the protective glue, the step of pressurizing and degassing the protective glue to remove air bubbles in the protective glue.
